(19) United States
(12) Patent Application Publication
(10) Pub. No.: US 2024/0198393 A1
(43) Pub. Date: Jun. 20, 2024

(54) SUBSTRATE TREATING APPARATUS AND CLEANING METHOD THEREOF

(71) Applicant: SEMES CO., LTD., Chungcheongnam-do (KR)

(72) Inventors: Yong Chul KWAK, Chungcheongnam-do (KR); Jung Hyun LEE, Chungcheongnam-do (KR); Jae Ho YOO, Seoul (KR); Kyo Sang YOON, Chungcheongnam-do (KR); Hye Bin BAEK, Incheon (KR)

(21) Appl. No.: 18/510,663

(22) Filed: Nov. 16, 2023

(30) Foreign Application Priority Data
Dec. 16, 2022 (KR) 10-2022-0176879

(51) Int. Cl. B08B 3/08; B08B 3/02; B08B 5/04; G03F 7/00

(52) U.S. Cl. CPC B08B 3/08; B08B 3/02; B08B 5/04; G03F 7/70925

(57) ABSTRACT

A substrate treating apparatus and a cleaning method thereof that can clean a nozzle tip and its surroundings in the presence of a source of contamination are provided. The substrate treating apparatus includes: a substrate support unit supporting a substrate; a spraying unit including a nozzle tip member, which has an outlet formed at an end thereof, and ejecting a treating solution onto the substrate using the nozzle tip member; and a standby port accommodating the nozzle tip member that has completed the ejection of the treating solution, wherein the substrate treating apparatus cleans the nozzle tip member and the inside of the standby port before the nozzle tip member sucks back a second chemical solution.

### CROSS-REFERENCE TO RELATED APPLICATION

This application claims priority from Korean Patent Application No. 10-2022-0176879 filed on Dec. 16, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate treating apparatus and a cleaning method thereof, and more particularly, to a substrate treating apparatus and a cleaning method thereof that can be utilized in a photolithography process.

### 2. Description of the Related Art

Semiconductor manufacturing processes may be continuously carried out within semiconductor manufacturing equipment and may be classified into front-end processes and back-end processes. Here, the front-end processes refer to processes of forming circuit patterns on a wafer to complete a semiconductor chip, while the back-end processes refer to processes of evaluating the performance of a completed product obtained through the front-end processes.

The semiconductor manufacturing equipment can be installed within a semiconductor manufacturing plant called a fab. Wafers go through various processes such as deposition, photolithography, etching, ion implantation, cleaning, packaging, and inspection, sequentially moving to equipment where each process is performed to produce semiconductors.

The photolithography process is a process for forming a pattern on a semiconductor substrate, and consists of processes such as coating, exposure, and development. In the coating process, a photosensitive material such as photoresist may be sprayed onto the semiconductor substrate through a nozzle to form a photosensitive film.

The nozzle may include a nozzle tip with an outlet for ejecting a solution, protruding toward the semiconductor substrate. The nozzle tip may be made of a metal or plastic resin (e.g., perfluoroalkoxy (PFA)).

In cases where the nozzle tip is made of a metal, it may corrode due to chemical reactions with the solution, which could potentially contaminate the solution. Additionally, if the nozzle tip is made of a plastic resin, static electricity may occur at the nozzle tip, leading to dust or fine fluids adhering to the outlet and contaminating the nozzle tip area or the solution.

### SUMMARY

Aspects of the present disclosure provide a substrate treating apparatus and a cleaning method thereof that can clean a nozzle tip and the area around the nozzle tip in the presence of a source of contamination.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a substrate support unit supporting a substrate; a spraying unit including a nozzle tip member, which has an outlet formed at an end thereof, and ejecting a treating solution onto the substrate using the nozzle tip member; and a standby port accommodating the nozzle tip member that has completed the ejection of the treating solution, wherein the substrate treating apparatus cleans the nozzle tip member and the inside of the standby port before the nozzle tip member sucks back a second chemical solution.

According to another aspect of the present disclosure, a cleaning method of a substrate treating apparatus includes: moving a nozzle tip member, which ejects a treating solution onto a substrate, into an internal space of a standby port; cleaning the nozzle tip member; cleaning the inside of the standby port; and allowing the nozzle tip member to suck back a second chemical solution.

According to another aspect of the present disclosure, a substrate treating apparatus includes: a substrate support unit supporting a substrate; a spraying unit including a nozzle tip member, which has an outlet formed at an end thereof, and ejecting a treating solution onto the substrate using the nozzle tip member; and a standby port accommodating the nozzle tip member that has completed the ejection of the treating solution, wherein the nozzle tip member and the standby port are sequentially cleaned before the nozzle tip member sucks back a chemical solution, the cleaning of the nozzle tip member and the cleaning of the standby port are repeated a plurality of times, once the nozzle tip member is cleaned, the nozzle tip member moves away from the internal space of the standby port, and the inside of the standby port is cleaned after the nozzle tip member is moved away, the standby port is cleaned once before cleaning the nozzle tip member, the nozzle tip member is cleaned once again after cleaning the standby port, and the chemical solution is a thinner.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary schematic view illustrating the internal structure of semiconductor manufacturing equipment that includes a substrate treating apparatus that can be utilized in a photolithography process;

FIG. 2 is a second exemplary schematic view illustrating the internal configuration of the semiconductor manufacturing equipment including the substrate treating apparatus that can be utilized in a photolithography process;

FIG. 3 is a block diagram of the semiconductor manufacturing equipment;

FIG. 4 is a schematic cross-sectional view illustrating the internal configuration of a substrate treating apparatus that performs a coating process on a substrate;

FIG. 5 is a first exemplary schematic view illustrating the nozzle tip member and standby port provided within the substrate treating apparatus of FIG. 4;

FIG. 6 is a second exemplary schematic view illustrating the nozzle tip member and standby port provided within the substrate treating apparatus of FIG. 4;

FIG. 7 is a first exemplary schematic view illustrating the contamination of the nozzle tip member (and its surroundings) of the substrate processing apparatus of FIG. 4;

FIG. 8 is a second exemplary schematic view illustrating the contamination of the nozzle tip member (and its surroundings) of the substrate processing apparatus of FIG. 4;

FIG. 9 is a first exemplary flowchart illustrating a cleaning method for the nozzle tip component (and its surroundings) of the substrate processing apparatus of FIG. 4;

FIG. 10 is a first exemplary schematic view illustrating the cleaning method of FIG. 9;

FIG. 11 is a second exemplary schematic view illustrating the cleaning method of FIG. 9;

FIG. 12 is a third exemplary schematic view illustrating the cleaning method of FIG. 9;

FIG. 13 is a fourth exemplary schematic view illustrating the cleaning method of FIG. 9;

FIG. 14 is a fifth exemplary schematic view illustrating the cleaning method of FIG. 9;

FIG. 15 is a sixth exemplary schematic view illustrating the cleaning method of FIG. 9;

FIG. 16 is a seventh exemplary schematic view illustrating the cleaning method of FIG. 9;

FIG. 17 is an eighth exemplary schematic view illustrating the cleaning method of FIGS. 9; and

FIG. 18 is a second exemplary flowchart of the cleaning method for the nozzle tip component (and its surroundings) of the substrate processing apparatus of FIG. 4.

### DETAILED DESCRIPTION

Embodiments of the present disclosure will hereinafter be described with reference to the attached drawings. The same reference numerals are used for the same components in the drawings, and redundant explanations of these will be omitted.

The present disclosure relates to a substrate treating apparatus and a cleaning method thereof that can be utilized in a photolithography process. The substrate treating apparatus of the present disclosure can clean a nozzle tip or the area around the nozzle tip in the presence of a source of contamination.

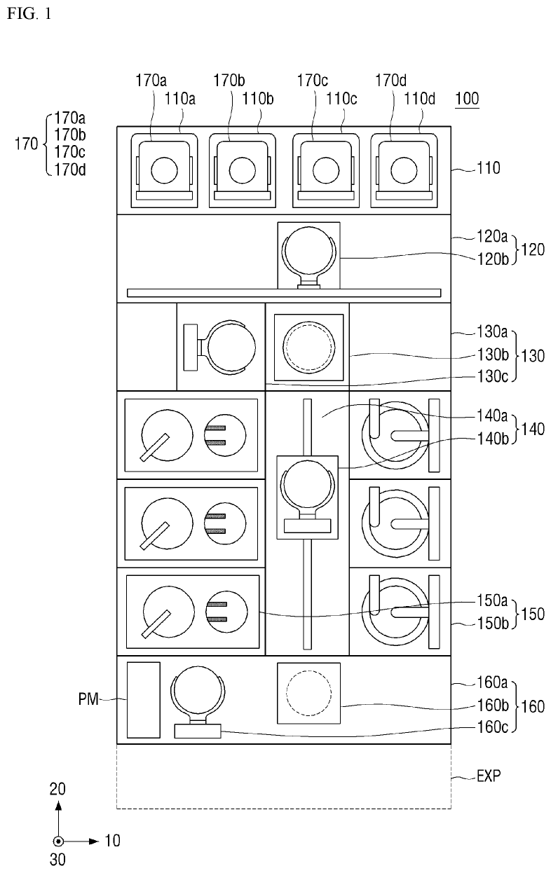

FIG. 1 is a first exemplary schematic view illustrating the internal structure of semiconductor manufacturing equipment that includes a substrate treating apparatus that can be utilized in a photolithography process. Referring to FIG. 1, semiconductor manufacturing equipment 100 may be configured to include load port units 110, an index module 120, a buffer module 130, a transfer module 140, process chambers 150, and an interface module 160.

The semiconductor manufacturing equipment 100 is a system for treating a semiconductor substrate through various processes such as coating, exposure, development, and heat treatment. For this purpose, the semiconductor manufacturing equipment 100 may be implemented as a multi-chamber substrate treating system including a plurality of process chambers 150 of the same type or different types, such as a chamber for performing a photoresist coating process, a chamber for performing an exposure process, a chamber for performing a development process, and a chamber for performing a heat treatment process.

The load port units 110 are provided to accommodate containers 170 loaded with multiple semiconductor substrates. The containers 170 may be, for example, front opening unified pods (FOUPs).

The containers 170 may be loaded onto or unloaded from the load port units 110. Also, the semiconductor substrates stored in the containers 170 may be loaded onto or unloaded from the load port units 110.

Although not illustrated in FIG. 1, the containers 170 may be loaded onto or unloaded from the load port units 110 by a container transporting device. Specifically, the containers 170 may be loaded onto the load port units 110 by mounting the containers 170 transported by the container transporting device in the load port units 110. Similarly, the containers 170 may be unloaded from the load port units 110 by gripping the containers 170 placed on the load port units 110 with the container transporting device. Here, the container transporting device may be, for example, an overhead hoist transporter (OHT).

The semiconductor substrates may be loaded onto or unloaded from the containers 170 placed on the load port units 110 by a substrate transfer robot 120b. Once the containers 170 are placed on the load port units 110, the substrate transfer robot 120b may approach the load port units 110 and may retrieve the semiconductor substrates from the containers 170. In this manner, the unloading of the semiconductor substrates may be performed.

Once the treatment of the semiconductor substrates is complete within the process chambers 150, the substrate transfer robot 120b may retrieve remove the semiconductor substrates from the buffer module 130 and place them back onto the containers 170. In this manner, the loading of the semiconductor substrates may be performed.

A plurality of load port units 110 may be disposed in front of the index module 120. For example, a first load port 110a, a second load port 110b, a third load port 110c, and a fourth load port 110d may be disposed in front of the index module 120.

When the load port units 110 are disposed in front of the index module 120, the containers 170 mounted on the load port units 110 may accommodate different types of items. For example, when four load port units 110, i.e., the first, second, third, and fourth load port units 110a, 110b, 110c, and 110d, are provided in front of the index module 120, a first container 170a on the first load port unit 110a to the far left may carry a wafer-type sensor, second and third containers 170b and 170c on the second and third load port units 110b and 110c, respectively, in the middle may carry substrates (or wafers), and a fourth container 170d on the fourth load port unit 110d to the far right may carry a consumable part such as a focus ring or an edge ring.

However, the present embodiment is not limited to this. Alternatively, the first, second, third, and fourth containers 170a, 170b, 170c, and 170d may all carry items of the same type. Yet alternatively, some of the first, second, third, and fourth containers 170a, 170b, 170c, and 170d may carry items of the same type, and the other containers may carry items of different types.

The index module 120 is disposed between the load port units 110 and the buffer module 130 and interfaces the transfer of the semiconductor substrates between the containers 170 on the load port units 110 and the buffer module 130. For this purpose, the index module 120 may include a substrate transfer robot 120b within a module housing 120a. At least one substrate transfer robot 120b may be provided within the module housing 120a.

Although not illustrated in FIG. 1, at least one buffer chamber may be provided within the index module 120. Untreated substrates may be temporarily stored in the buffer chamber before being transferred to the buffer module 130, and treated substrates may also be temporarily stored before being inserted into the containers 170 on the load port units 110. The buffer chamber may be provided on a sidewall that is not adjacent to either the load port units 110 or the buffer module 130, but the present disclosure is not limited thereto. Alternatively, the buffer chamber may be provided on a sidewall adjacent to the buffer module 130.

A front-end module (FEM) may be provided on one side of the buffer module 130. The FEM may include the load port units 110 and the index module 120 and may be implemented as an equipment FEM (EFEM) or a substrate FEM (SFEM).

Meanwhile, the first, second, third, and fourth load port units 110a, 110b, 110c, and 110d may be arranged in a horizontal direction (or a first direction 10), but the present disclosure is not limited thereto. Alternatively, the first, second, third, and fourth load port units 110a, 110b, 110c, and 110d may be stacked in a vertical direction, in which case, the FEM may be configured as, for example, a vertically stacked EFEM.

The buffer module 130 functions as a buffer chamber between the input and output ports of the semiconductor manufacturing equipment 100. The buffer module 130 may include a buffer stage 130b, which temporarily stores the semiconductor substrates. A single buffer stage 130b may be disposed between the index module 120 and the transfer module 140, but the present disclosure is not limited thereto. Alternatively, a plurality of buffer stages 130b may be disposed between the index module 120 and the transfer module 140.

The buffer module 130 may be equipped with not only the buffer stage(s) 130b but also a substrate transfer robot 130c within a module housing 130a. When a plurality of buffer stages 130b are provided, the substrate transfer robot 130c transfers the semiconductor substrates between the buffer stages 130b.

The buffer module 130 may be loaded or unloaded with the semiconductor substrates by a substrate transfer robot 140b of the transfer module 140. The buffer module 130 may also be loaded or unloaded with the semiconductor substrates by the substrate transfer robot 120b of the index module 120.

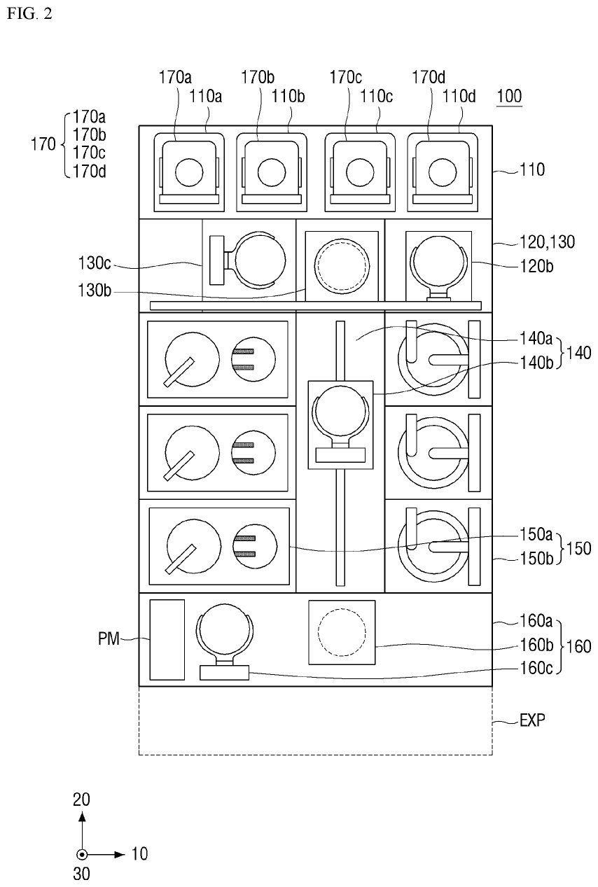

The buffer module 130 may be disposed at the rear end of the index module 120. That is, the buffer module 130 may not necessarily be disposed on the same line as the index module 120, but the present disclosure is not limited thereto. Alternatively, as illustrated in FIG. 2, the buffer module 130 may be disposed on the same line as the index module 120. In this case, the substrate transfer robot 120b of the index module 120, the substrate transfer robot 130c of the buffer module 130, and the buffer stage(s) 130b may be disposed within a single module housing. FIG. 2 is a second exemplary schematic view illustrating the internal configuration of the semiconductor manufacturing equipment including the substrate treating apparatus that can be utilized in a photolithography process.

Referring back to FIG. 1, the transfer module 140 interfaces the transfer of the semiconductor substrates between the buffer module 130 and the process chambers 150. To this end, the transfer module 140 may be equipped with the substrate transfer robot 140b within the module housing 140a. At least one substrate transfer robot 140b may be provided within the module housing 140a.

The substrate transfer robot 140b transfers untreated substrates from the buffer module 130 to the process chambers 150, or transfers treated substrates from the process chambers 150 to the buffer module 130. For this purpose, sides of the transfer module 140 may be connected to the buffer module 130 and the process chambers 150. Meanwhile, the substrate transfer robot 140b may be provided to be freely movable.

The process chambers 150 processes the semiconductor substrates. A plurality of process chambers 150 may be disposed around the transfer module 140. In this case, the process chambers 150 receive the semiconductor substrates from the transfer module 140, treat (or process) the received semiconductor substrates, and then provide the treated semiconductor substrates back to the transfer module 140.

The process chambers 150 may be cylindrical or polygonal in shape. The process chambers 150 may be formed of alumite with anodized surfaces may be hermetically sealed on the inside. Meanwhile, the process chambers 150 may also be formed in various shapes other than a cylindrical or polygonal shape.

The interface module 160 transfers the semiconductor substrates. The interface module 160 may include a module housing 160a, a buffer stage 160b, and a substrate transfer robot 160c. The buffer stage 160b and the substrate transfer robot 160c are positioned within the module housing 160a. A single buffer stage 160b may be provided, but the present disclosure is not limited thereto. Alternatively, a plurality of buffer stages 160b may be provided, in which case, the buffer stages 160b may be a predetermined distance apart from one another and may be stacked on one another.

The substrate transfer robot 160c transports the semiconductor substrates between the buffer stage 160b and an exposure device EXP. The buffer stage 160b temporarily stores semiconductor substrates yet to be processed by the exposure device EXP before transferring them to the exposure device EXP, or temporarily stores semiconductor substrates that have processed by the exposure device EXP. Only the aforementioned buffers and robots may be provided in the interface module 160 without any chambers for performing particular processes on the semiconductor substrates.

Meanwhile, a purge module PM may be provided in the module housing 160a of the interface module 160, but the present disclosure is not limited thereto. Alternatively, the purge module PM may also be provided at various other locations such as where the exposure device EXP is connected at the rear end of the interface module 160 or on a side of the interface module 160.

As previously described, the buffer stage(s) 130b may be provided in the buffer module 130, and the buffer stage(s) 160b may be provided in the interface module 160. The buffer stage(s) 130b may be defined as a first buffer stage or first buffer stages, and the buffer stage(s) 160b may be defined as a second buffer stage or second buffer stages to distinguish between the buffer stage(s) 130b and the buffer stage(s) 160b.

Also, as previously explained, the substrate transfer robot 120b may be provided in the index module 120, the substrate transfer robot 130c may be provided in the buffer module 130, the substrate transfer robot 140b may be provided in the transfer module 140, and the substrate transfer robot 160c may be provided in the interface module 160. The substrate transfer robots 120b, 130c, 140b, and 160c are defined as first, second, third, and fourth transfer robots, respectively, to distinguish between the substrate transfer robots 120b, 130c, 140b, and 160c.

The semiconductor manufacturing equipment 100 may be formed to have an in-line platform structure, as illustrated in FIG. 1. In this case, the process chambers 150 may be arranged in an in-line manner with respect to the transfer module 140, and different types of process chambers 150 may be arranged in series on both sides of the transfer module 140 to correspond to each other. However, the present disclosure is not limited to this. Alternatively, the semiconductor manufacturing equipment 100 may be formed to have a cluster platform structure or a quad platform structure.

Substrate treating apparatuses, i.e., the process chambers 150 provided in the semiconductor manufacturing equipment 100, will hereinafter be described. As previously described, the semiconductor manufacturing equipment 100 may include a plurality of process chambers 150, which are arranged in an in-line manner with respect to the transfer module 140. In this case, different types of process chambers 150 may be arranged in series on both sides of the transfer module 140 to correspond to each other. One type of process chamber 150 may be a substrate treating apparatus 150a that performs a heat treatment process on a substrate, and another type of process chamber 150 may be a substrate treating apparatus 150b that performs a coating or developing process on a substrate.

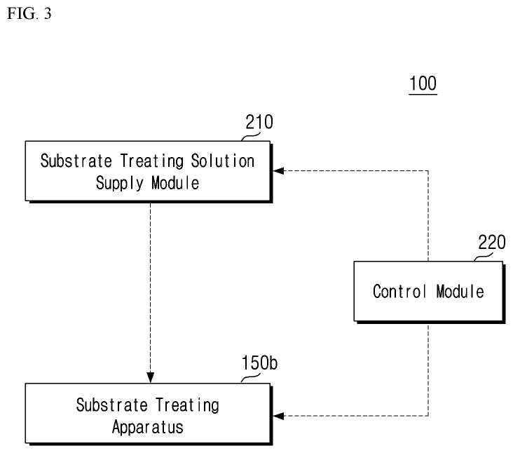

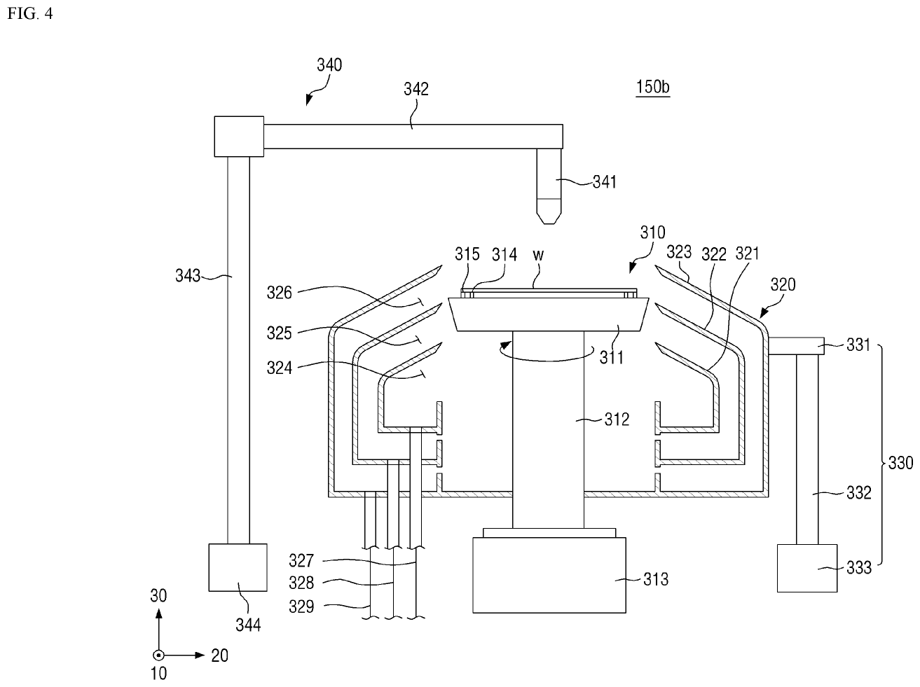

FIG. 3 is a block diagram of the semiconductor manufacturing equipment. FIG. 4 is a schematic cross-sectional view illustrating the internal configuration of a substrate treating apparatus that performs a coating process on a substrate.

Referring to FIGS. 3 and 4, the substrate treating apparatus 150b is an apparatus that treats a substrate W using chemical solutions. The substrate treating apparatus 150b may use the chemical solutions to form photoresist on the substrate W. Alternatively, the substrate treating apparatus 150b may use the chemical solutions to remove the photoresist from the substrate W. The substrate treating apparatus 150b may be implemented as a cleaning process chamber that treats the substrate W using the chemical solutions.

Here, the chemical solutions may be liquid substances (e.g., organic solvents) or gaseous substances. The chemical solutions may have high volatility, generate fumes, or have high viscosity and are thus residue-prone. The chemical solutions may be selected from among materials that include isopropyl alcohol (IPA) components, sulfuric acid components (e.g., sulfuric peroxide mixture (SPM) containing sulfuric acid and hydrogen peroxide), ammonia components (e.g., SC-1 (i.e., H₂O₂+NH₄OH)), hydrofluoric acid components (e.g., diluted hydrogen fluoride (DHF)), and phosphoric acid components. Chemical solutions for treating the substrate W may be defined as substrate treating solutions.

When the substrate treating apparatus 150b is applied for a cleaning process, the substrate treating apparatus 150b may rotate the substrate W using a spin head and may provide a chemical solution onto the surface of the substrate W using a nozzle. As illustrated in FIG. 4, when configured as a liquid treating chamber, the substrate treating apparatus 150b may include a substrate support unit 310, a treating solution recovery unit 320, a lifting unit 330, and a spraying unit 340.

The substrate support unit 310 is a module that supports the substrate W. The substrate support unit 310 may rotate the substrate W in a direction perpendicular to the third direction 30, for example, in the first direction 10 or a second direction 20, during the treatment of the substrate W. The substrate support unit 310 may be disposed within the solution recovery unit 320 to recover substrate treating solutions used during the treatment of the substrate W.

The substrate support unit 310 may be configured to include a spin head 311, a rotary shaft 312, a rotary driving module 313, support pins 314, and guide pins 315.

The spin head 311 rotates along the direction of rotation of the rotary shaft 312, which is perpendicular to the third direction 30. The spin head 311 may be provided to have the same shape as the substrate W, but the present disclosure is not limited thereto. The spin head 311 may also be provided to have a different shape from the substrate W.

The rotary shaft 312 generates a rotational force using energy provided by the rotary driving module 313. The rotary shaft 312 may be coupled to both the rotary driving module 313 and the spin head 311 and may deliver the rotational force from the rotary driving module 313 to the spin head 311. The spin head 311 rotates along with the rotary shaft 312, in which case, the substrate W attached to the spin head 311 may also rotate with the spin head 311.

The support pins 314 and the guide pins 315 fix the substrate W on the spin head 311. The support pins 314 support the bottom surface of the substrate W on the spin head 311, while the guide pins 315 support the side surfaces of the substrate W. Multiple support pins 314 and multiple guide pins 315 may be installed on the spin head 311.

The support pins 314 may be disposed with a circular ring shape as a whole. As a result, the support pins 314 can support the bottom surface of the substrate W at a predetermined distance from the top of the spin head 311.

The guide pins 315, which are chucking pins, may support the substrate W in place and prevent the substrate W from being detached from its original position when the spin head 311 rotates.

The treating solution recovery unit 320 recovers the substrate treating solutions used to treat the substrate W. The treating solution recovery unit 320 may be installed around the substrate support unit 310, providing space for performing a treating operation on the substrate W.

After the substrate W is attached and fixed on the substrate support unit 310 and starts rotating under the control of the substrate support unit 310, the spraying unit 340 may inject substrate treating solutions onto the substrate W under the control of a control module 220. Then, due to the centrifugal force generated by the rotational force of the substrate support unit 310, the substrate treating solutions ejected onto the substrate W may be dispersed in the directions where the treating solution recovery unit 320 is located. In this case, the treating solution recovery unit 320 may recover the substrate treating solutions when the substrate treating solutions flow into its interior through inflow ports (i.e., a first opening 324 of a first recovery tank 321, a second opening 325 of a second recovery tank 322, and a third opening 326 of a third recovery tank 323).

The treating solution recovery unit 320 may be configured include multiple recovery tanks. For example, the treating solution recovery unit 320 may include three recovery tanks. In this case, the substrate treating solution used to treat the substrate W may be separated and recovered, enabling the recycling of the substrate treating solutions.

The treating solution recovery unit 320 may include three recovery tanks, i.e., the first, second, and third recovery tanks 321, 322, and 323. The first, second, and third recovery tanks 321, 322, and 323 may be implemented, for example, as bowls.

The first, second, and third recovery tanks 321, 322, and 323 may recover different substrate treating solutions. For example, the first recovery tank 321 may recover a rinse liquid (e.g., deionized (DI) water), the second recovery tank 322 may recover a first chemical solution, and the third recovery tank 323 may recover a second chemical solution.

The first, second, and third recovery tanks 321, 322, and 323 may be connected to recovery lines 327, 328, and 329 extending in a downward direction (or the third direction 30) from the bottom surfaces of the first, second, and third recovery tanks 321, 322, and 323. First, second, and third treating solutions recovered through the first, second, and third recovery tanks 321, 322, and 323, respectively, may be processed and made reusable through a treating solution regeneration system (not illustrated).

The first, second, and third recovery tanks 321, 322, and 323 may be provided in a circular ring shape surrounding the substrate support unit 310. The size of the first, second, and third recovery tanks 321, 322, and 323 may gradually increase from the first recovery tank 321 to the third recovery tank 323 (e.g., in the second direction 20). When the distance between the first and second recovery tanks 321 and 322 is defined as a first gap and the distance between the second and third recovery tanks 322 and 323 is defined as a second gap, the first gap may be the same as the second gap, but the present disclosure is not limited thereto. Alternatively, the first gap may differ from the second gap. In other words, the first gap may be larger or smaller than the second gap.

The lifting unit 330 is for rectilinearly moving the treating solution recovery unit 320 in the vertical direction (or the third direction 30). The lifting unit 330 may adjust the relative height of the treating solution recovery unit 320 with respect to the substrate support unit 310 (or the substrate W).

The lifting unit 330 may be configured to include a bracket 331, a first support shaft 332, and a first driving module 333.

The bracket 331 is fixed to the outer wall of the treating solution recovery unit 320. The bracket 331 may be coupled with the first supporting axis 332, which moves in the vertical direction under the control of the first driving module 333.

When the substrate W is attached to the substrate support unit 310, the substrate support unit 310 may be positioned above the treating solution recovery unit 320. Similarly, when the substrate W is detached from the substrate support unit 310, the substrate support unit 310 may also be positioned above the treating solution recovery unit 320. In such cases, the lifting unit 330 may lower the treating solution recovery unit 320.

When the substrate W is being treated, the substrate treating solutions ejected onto the substrate W may be recovered into one of the first, second, and third recovery tanks 321, 322, and 323, depending on their types. Even in this case, the lifting unit 330 may lift or lower the treating solution recovery unit 320 to each desired position. For example, if the first treating solution is used, the lifting unit 330 may lift the treating solution recovery unit 320 to a height corresponding to the first opening 324 of the first recovery tank 321.

Meanwhile, the lifting unit 330 may adjust the relative height of the treating solution recovery unit 320 with respect to the substrate support unit 310 (or the substrate W) by rectilinearly moving the substrate support unit 310 in the vertical direction.

However, the present disclosure is not limited to this. Alternatively, the lifting unit 330 may adjust the relative height of the treating solution recovery unit 320 with respect to the substrate support unit 310 (or the substrate W) by rectilinearly moving both the substrate support unit 310 and the treating solution recovery unit 320 at the same time in the vertical direction.

The spraying unit 340 is a module that supplies substrate treating solutions onto the substrate W during the treatment of the substrate W. At least one spraying unit 340 may be installed within the substrate treating apparatus 150b. When a plurality of spraying units 340 are installed within the substrate treating apparatus 150b, the spraying units 340 may inject different substrate treating solutions onto the substrate W.

The spraying unit 340 may be configured to include a nozzle structure 341, a nozzle support module 342, a second support shaft 343, and a second driving module 344.

The nozzle structure 341 is installed at one end of the nozzle support module 342. The nozzle structure 341 may be moved to a processing position or a standby position by the second driving module 344.

Here, the processing position refers to a region above the substrate W, while the standby position refers to regions other than the processing position. To eject a substrate treating solution onto the substrate W, the nozzle structure 341 may be moved to the processing position. Then, after ejecting the substrate treating solution onto the substrate W, the nozzle structure 341 may move away from the processing position to the standby position.

The nozzle support module 342 supports the nozzle structure 341. The nozzle support module 342 may extend in a direction corresponding to the length direction of the spin head 311. In other words, the length direction of the nozzle support module 342 may be provided along the second direction 20.

The nozzle support module 342 may be coupled to the second support shaft 343, which extends in a vertical direction with respect to its length direction. The second support shaft 343 may extend in a direction corresponding to the height direction of the spin head 311. In other words, the length direction of the second support shaft 343 can be provided along the third direction 30.

The second driving module 344 is a module that rotates and elevates the second support shaft 343 and the nozzle support module 342, which is linked with the second support shaft 343. As a result, the nozzle structure 341 may be moved to the processing position or the standby position.

Referring again to FIG. 3, the semiconductor manufacturing equipment 100 may include the substrate treating apparatus 150b, which performs a coating process on the substrate W. The semiconductor manufacturing equipment 100 may also include a substrate treating solution supply module 210 and the control module 220.

The substrate treating solution supply module 210 provides substrate treating solutions within the substrate treating apparatus 150b. To this end, the substrate treating solution supply module 210 may be connected to the spraying unit 340 and operate under the control of the control module 220.

The control module 220 controls the overall operations of the components of the semiconductor manufacturing equipment 100. For example, the control module 220 may control substrate insertion and withdrawal performed by the substrate transport robots 120b, 130c, and 140b of the index module 120, the buffer module 130, and the transfer module 140 and may also control substrate processing in the processing chambers 150. Additionally, the control module 220 may also control the operation of the substrate treating solution supply module 210.

The control module 220 may include: a process controller, which consists of a microprocessor (or a computer) that executes the control of the semiconductor manufacturing equipment 100; a user interface, which includes a keyboard for an operator to input commands and manage the semiconductor manufacturing equipment 100 and a display to visualize the operating status of the semiconductor manufacturing equipment 100; and a memory unit, which stores control programs for executing processes under the control of the process controller or programs (or processing recipes) for executing processes in the semiconductor manufacturing equipment 100 based on various data and processing conditions. The user interface and the memory unit may be connected to the process controller. The processing recipes may be stored on a storage medium within the memory unit, and the storage medium may be a hard disk, a removable disc such as a compact disc read-only memory (CD-ROM) or a digital versatile disc (DVD), or a semiconductor memory such as a flash memory.

Meanwhile, the substrate treating solution supply module 210 and the control module 220 may also be included within the substrate treating apparatus 150b. In this case, the control module 220 may control the substrate treating solution supply module 210 and the components of the substrate treating apparatus 150b.

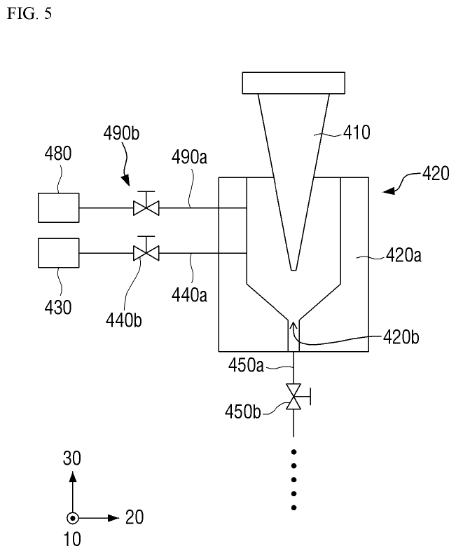

As previously described, the nozzle structure 341 may include a nozzle tip member 410, which protrudes toward the substrate W and has an outlet for ejecting a substrate treating solution. During a coating process in photolithography, the nozzle tip member 410 sprays a photosensitive solution such as photoresist onto the substrate W. Therefore, when the coating process is completed, the nozzle tip member 410, which may have adsorbed the photosensitive solution, needs to be cleaned. In this case, the nozzle tip member 410 may move to where a standby port 420 is located, and may use a cleaning solution within the standby port 420 to remove the adsorbed photosensitive solution. FIG. 5 is a first exemplary schematic view illustrating the nozzle tip member and standby port provided within the substrate treating apparatus of FIG. 4.

The first chemical solution supply unit 430 may provide the first chemical solution to the internal space of the standby port 420 through a first chemical solution supply line 440a. The first chemical may be a solution for cleaning the surface of the nozzle tip member 410.

On the first chemical solution supply line 440a, a first shutoff valve 440b may be installed to control the flow of the first chemical solution. The first chemical solution supply line 440a may be connected to the internal space of the standby port 420 by penetrating the side of the standby port 420.

The standby port 420 may include an outlet 420b at the bottom of a body part 420a to eject the first chemical solution injected thereinto to the outside. A chemical ejection line 450a may be connected to the outlet 420b of the standby port 420 to eject the first chemical outside, and a second shutoff valve 450b may be installed on the chemical ejection line 450a to control the flow of the first chemical.

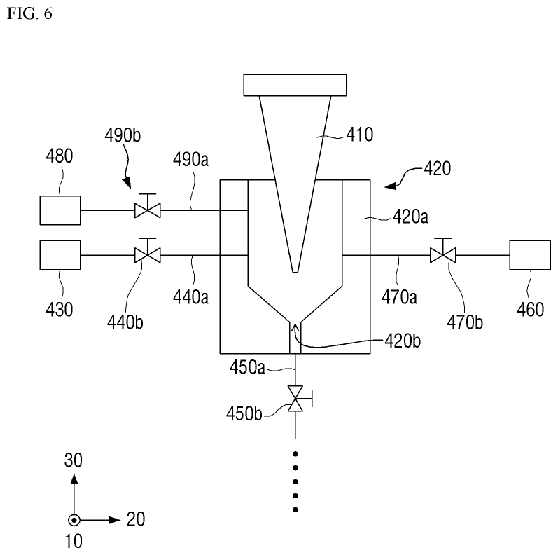

Meanwhile, not only the first chemical solution supply unit 430 but also a second chemical solution supply unit 460 may be connected to the standby port 420. FIG. 6 is a second exemplary schematic view illustrating the nozzle tip member and standby port provided within the substrate treating apparatus of FIG. 4.

The second chemical solution supply unit 460 may provide the second chemical solution to the internal space of the standby port 420 through a second chemical solution supply line 470a. The second chemical solution may be for cleaning the surface of the substrate W. For example, the second chemical solution may be used to remove photoresist on the surface of the substrate W. The second chemical solution may be, for example, a thinner.

On the second chemical solution supply line 470a, a third shutoff valve 470b may be installed to control the flow of the second chemical solution. The second chemical solution supply line 470a, like the first chemical solution supply line 440a, may be connected to the internal space of the standby port 420 by penetrating the side of the standby port 420.

The second chemical solution may be provided to the standby port 520 after the supply of the first chemical solution. Thus, only one chemical solution supply unit may be connected to the standby port 420. That is, only the first chemical solution supply unit 430 may be connected to the standby port 420 and may sequentially provide the first and second chemical solutions. In a case where the first chemical solution supply unit 430 sequentially provides the first and second chemical solutions, the first and second chemical solutions may be the same. For example, the first and second chemical solutions may both be thinners.

Meanwhile, a third chemical solution supply unit 480 can also be connected to the standby port 420. The third chemical solution supply unit 480 may provide the third chemical solution to the internal space of the standby port 420 via a third chemical solution supply line 490a. The third chemical solution may be for cleaning the inner space of the standby port 420.

On the third chemical solution supply line 490a, a fourth shutoff valve 490b may be installed to control the flow of the third chemical solution. The third chemical solution supply line 490a, like the first and second chemical solution supply lines 440a and 470a, may be connected to the internal space of the standby port 420 by penetrating the side of the standby port 420.

Meanwhile, the third chemical solution supply line 490a may be disposed on a higher level than the first chemical solution supply line 440a to clean the inner space of the standby port 420, but the present disclosure is not limited thereto. Alternatively, the third chemical solution supply line 490a may be disposed on the same level as the first chemical solution supply line 440a. Yet alternatively, the third chemical solution supply line 490a may be disposed on a lower level than the first chemical solution supply line 440a.

Meanwhile, the first chemical solution supply unit 430 may provide both a chemical solution for cleaning the surface of the nozzle tip member 410, i.e., the first chemical solution, and a chemical solution for cleaning the inner space of the standby port 420, i.e., the third chemical solution. The first chemical solution supply unit 430 may sequentially provide the first and third chemical solutions, and the first and third chemical solutions may be the same. In this case, the third chemical solution supply unit 480, the third chemical solution supply line 490a, and the fourth shutoff valve 490b may not be provided.

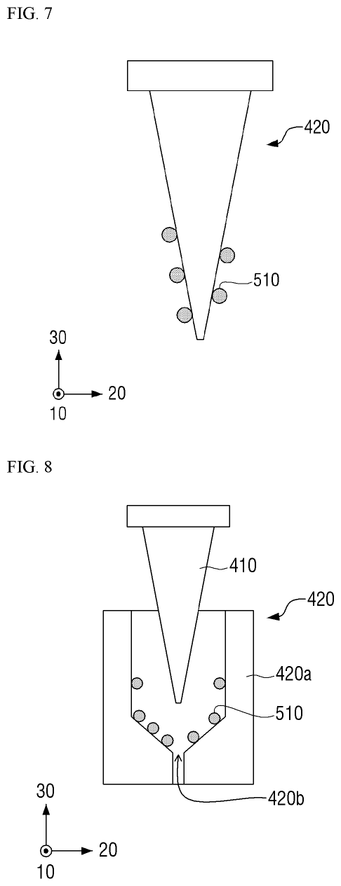

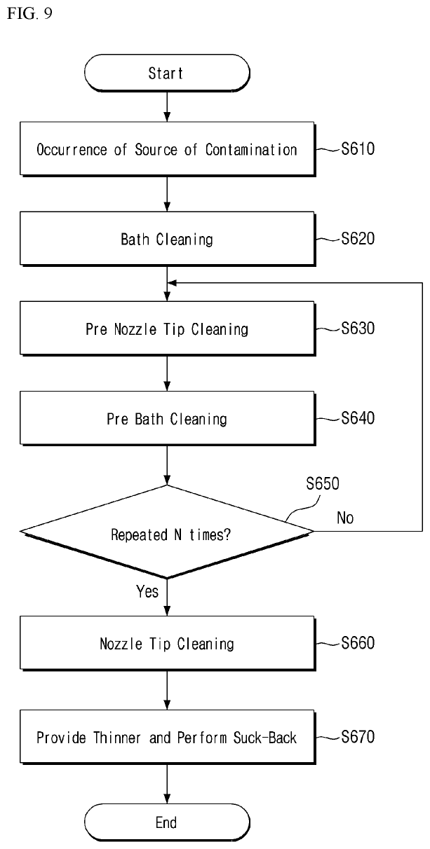

As previously explained, the nozzle tip member 410 or its surroundings may be contaminated due to corrosion or static electricity, which may lead to the contamination of chemical solutions. For example, as illustrated in FIG. 7, foreign substances 510 such as particles may adhere to the surface of the nozzle tip member 410, contaminating the nozzle tip member 410. Alternatively, as illustrated in FIG. 8, the foreign substances 510 may adhere to the inner surface of the standby port 420, contaminating the surroundings of the nozzle tip member 410. FIG. 7 is a first exemplary schematic view illustrating the contamination of the nozzle tip member (and its surroundings) of the substrate processing apparatus of FIG. 4. FIG. 8 is a second exemplary schematic view illustrating the contamination of the nozzle tip member (and its surroundings) of the substrate processing apparatus of FIG. 4.

If there is a source of contamination, the nozzle tip member 410 or its surroundings may be cleaned. FIG. 9 is a first exemplary flowchart illustrating a cleaning method for the nozzle tip component (and its surroundings) of the substrate processing apparatus of FIG. 4.

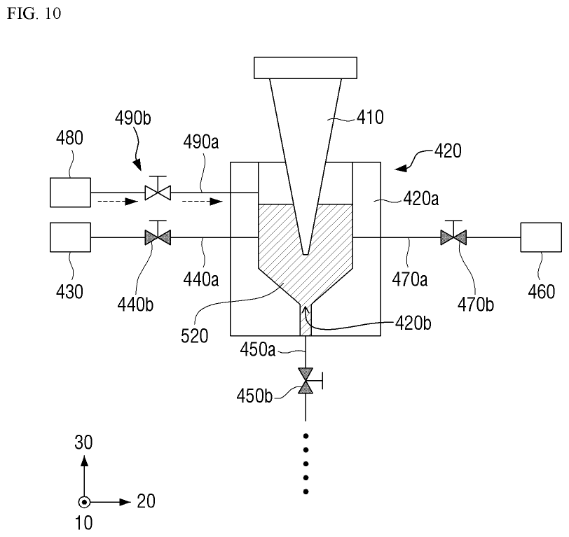

Referring to FIG. 9, if it is determined that a source of contamination has occurred (S610), a bath cleaning process (S620) is performed. In this case, the third chemical solution supply unit 480 may provide a third chemical solution 520 to the internal space of the standby port 420, and the inner surface of the standby port 420 may be cleaned by the third chemical solution 520. The bath cleaning process may be performed once. FIG. 10 is a first exemplary schematic view illustrating the cleaning method of FIG. 9.

The occurrence of the source of contamination may be determined visually by the operator, but the present disclosure is not limited thereto. Alternatively, the occurrence of the source of contamination may be determined using equipment such as a camera sensor.

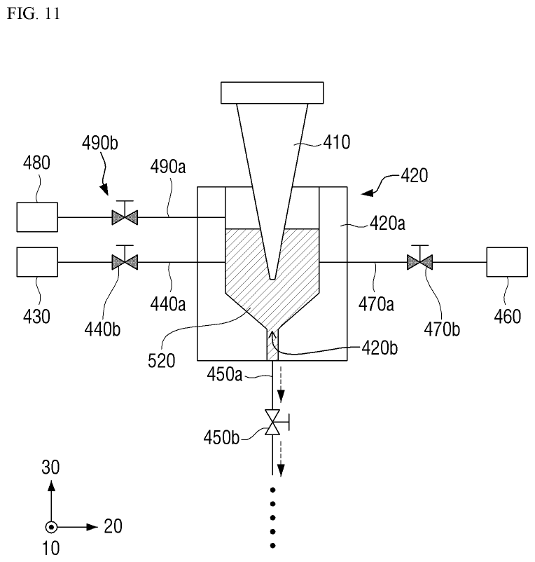

In step S620, the third chemical solution 520 may be ejected to the outside through the chemical ejection line 450a a predetermined amount of time after being introduced into the internal space of the standby port 420, but the present disclosure is not limited thereto. Alternatively, in step S620, the third chemical solution 520 may be ejected to the outside through the chemical ejection line 450a immediately after entering the internal space of the standby port 420. FIG. 11 is a second exemplary schematic view illustrating the cleaning method of FIG. 9.

However, the bath cleaning process alone may not be able to thoroughly clean the nozzle tip member 410 or its surroundings. In this case, if a nozzle tip cleaning process is performed immediately followed by a thinner suck-back process while the source of contamination is still present, the source of contamination may also be sucked back or contaminants may remain on the inner surface of the standby port 420. Therefore, the following steps are performed consecutively.

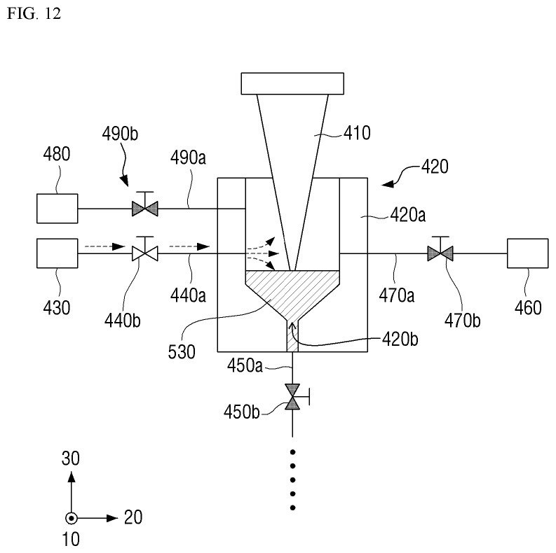

Thereafter, a pre-nozzle tip cleaning process (S630) is performed. In this case, the first chemical solution supply unit 430 may provide a first chemical solution 530 toward the nozzle tip member 410 located in the internal space of the standby port 420, and the surface of the nozzle tip member 410 may be cleaned by the first chemical solution 530. FIG. 12 is a third exemplary schematic view illustrating the cleaning method of FIG. 9.

In step S630, the first chemical solution 530 may be ejected to the outside through the chemical ejection line 450a a predetermined amount of time after being into the internal space of the standby port 420, but the present disclosure is not limited thereto. Alternatively, in step S630, the first chemical solution 530 may be ejected to the outside through the chemical ejection line 450a immediately after entering the internal space of the standby port 420.

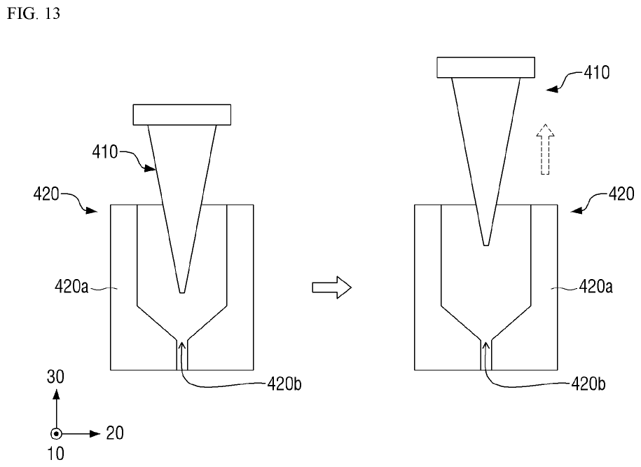

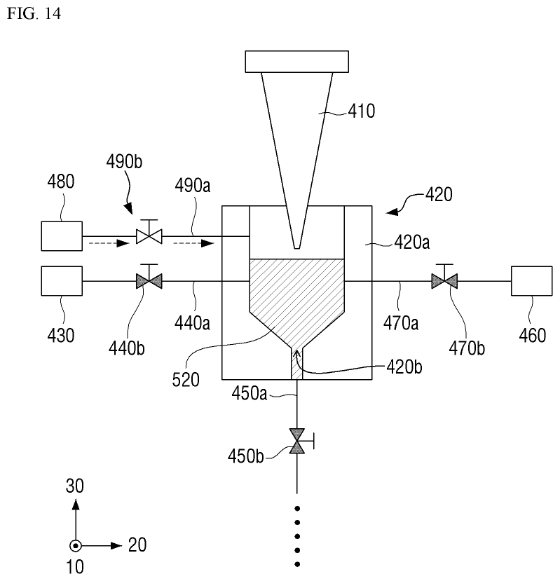

Thereafter, a pre-bath cleaning process (S640) is performed. In this case, as illustrated in FIG. 13, the nozzle tip member 410 is retracted from the outlet 420b of the standby port 420. Then, as illustrated in FIG. 14, the third chemical solution supply unit 480 may provide the third chemical solution 520 to the internal space of the standby port 420. As previously described, the inner space of the standby port 420 may be cleaned by the third chemical solution 520. FIG. 13 is a fourth exemplary schematic view illustrating the cleaning method of FIG. 9. FIG. 14 is a fifth exemplary schematic view illustrating the cleaning method of FIG. 9.

In step S640, the third chemical solution 520 may be ejected to the outside through the chemical ejection line 450a a predetermined amount of time after being introduced into the internal space of the standby port 420, but the present disclosure is not limited thereto. Alternatively, in step S640, the third chemical solution 520 may be ejected to the outside through the chemical ejection line 450a immediately after entering the internal space of the standby port 420.

Both the pre-nozzle tip cleaning process (S630) and the pre-bath cleaning process (S640) may be repeated N times (S650). Here, “N” refers to a natural number greater than or equal to 2, and “N times” means multiple times. The number of repetitions for the pre-nozzle tip cleaning process (S630) and the pre-bath cleaning process (S640) may be determined in advance based on statistical data acquired from experiments, but the present disclosure is not limited thereto. Alternatively, the pre-nozzle tip cleaning process (S630) and the pre-bath cleaning process (S640) may be performed only once or may not be performed at all.

For example, in a case where two nozzle tip members 410 are alternately used for dispensing substrate treating solutions and the source of contamination occurs in one of the two nozzle tip members 410, the pre-nozzle tip cleaning process (S630) and the pre-bath cleaning process (S640) may not be performed for the corresponding nozzle tip member 410. Also, in a case where ten nozzle tip members 410 are used at regular intervals of time for dispensing the semiconductor treatment solution, the pre-nozzle tip cleaning process (S630) and the pre-bath cleaning process (S640) may be performed one or two times for each of the ten nozzle tip members 410.

After sequentially performing the pre-nozzle tip cleaning process (S630) and the pre-bath cleaning process (S640), the interior of the nozzle tip member 410 and the standby port 420 may be inspected. The control module 220 may determine whether any foreign materials 510 remain on the inner spaces of the nozzle tip member 410 and the standby port 420 based on the results of the inspection. If it is determined that the foreign materials 510 remain, the control module 220 may allow the pre-nozzle tip cleaning process (S630) and the pre-bath cleaning process (S640) to be performed again.

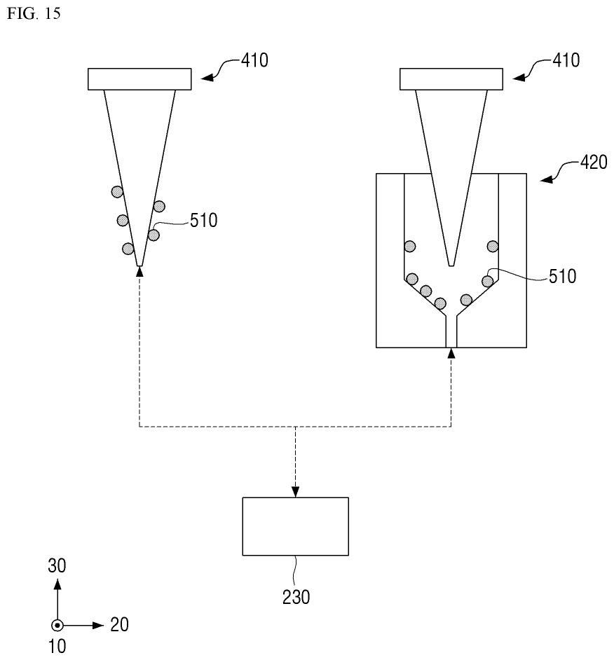

The inspection of the interior of the nozzle tip member 410 and the standby port 420 may be performed by an inspection module 230, as illustrated in FIG. 15. The inspection module 230 may be, for example, a camera module. In this case, the control module 220 may determine whether the foreign materials 510 remain on the inner spaces of the nozzle tip member 410 and the standby port 420 based on image information obtained by the camera module. FIG. 15 is a sixth exemplary schematic view illustrating the cleaning method of FIG. 9.

Once the repeated execution of the pre-nozzle tip cleaning process (S630) and the pre-bath cleaning process (S640) is completed, a nozzle tip cleaning process (S660) is performed. In this case, the first chemical solution supply unit 430 may provide the first chemical solution 530 to the nozzle tip member 410 located in the internal space of the standby port 420, and the surface of the nozzle tip member 410 may be cleaned by the first chemical solution 530. The nozzle tip cleaning process (S660) may be performed once.

In step S660, the first chemical solution 530 may be ejected to the outside through the chemical ejection line 450a a predetermined amount of time after being into the internal space of the standby port 420, but the present disclosure is not limited thereto. Alternatively, in step S660, the first chemical solution 530 may be ejected to the outside through the chemical ejection line 450a immediately after entering the internal space of the standby port 420.

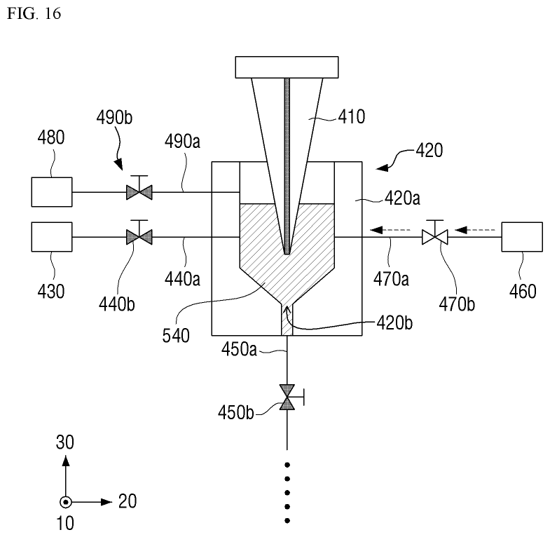

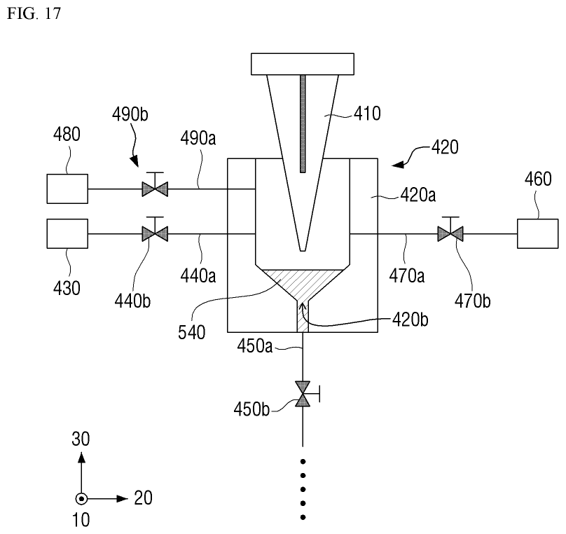

Thereafter, a thinner is provided, and a suck-back process is performed (S670). In this case, the second chemical solution supply unit 460 may supply a second chemical solution 540 into the internal space of the standby port 420, as illustrated in FIG. 16. The nozzle tip member 410 may suck back the second chemical solution 540 introduced into the internal space of the standby port 420, as illustrated in FIG. 17. FIG. 16 is a seventh exemplary schematic view illustrating the cleaning method of FIG. 9. FIG. 17 is an eighth exemplary schematic view illustrating the cleaning method of FIG. 9.

Meanwhile, the inspection module 230 may also be used to determine whether a source of contamination has occurred on the surface of the nozzle tip member 410 or in the inner space of the standby port 420. That is, the control module 220 may determine whether there are foreign materials 510 adsorbed on the surface of the nozzle tip member 410 based on the results of the inspection performed by the inspection module 230, and may thereby determine whether a source of contamination has occurred on the surface of the nozzle tip member 410. Alternatively, the control module 220 may determine whether there are foreign materials 510 adsorbed on the inner space of the standby port 420 based on the results of the inspection performed by the inspection module 230, and may thereby determine whether a source of contamination has occurred in the inner space of the standby port 420.

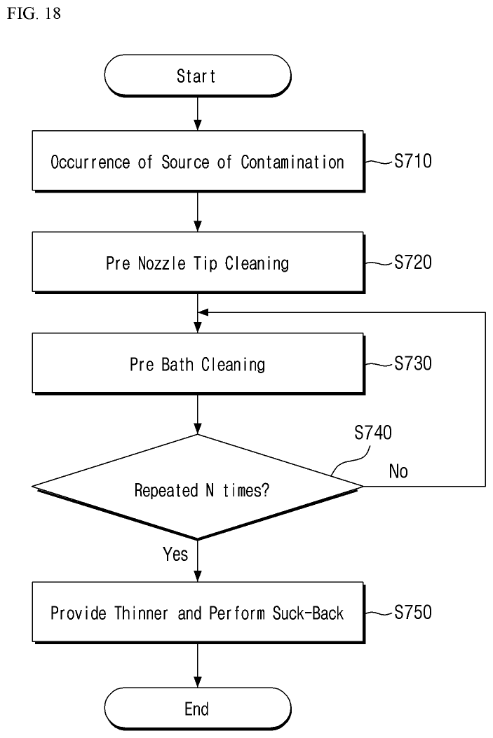

Meanwhile, referring to a cleaning method of FIG. 18, if it is determined in step S710 that a source of contamination has occurred, a bath cleaning process may not be performed, but a pre-nozzle tip cleaning process (S720) and a pre-bath cleaning process (S730) may be sequentially performed.

In this case, when the repeated execution of the pre-nozzle tip cleaning process (S720) and the pre-bath cleaning process (S730) is completed (S740), a thinner may be provided, and a suck-back process may be performed (S750).

Alternatively, when the repeated execution of the pre-nozzle tip cleaning process (S720) and the pre-bath cleaning process (S730) is completed (S740), a bath cleaning process and a nozzle tip cleaning process may be sequentially performed before step S750.

Yet alternatively, when the repeated execution of the pre-nozzle tip cleaning process (S720) and the pre-bath cleaning process (S730) is completed (S740), only the nozzle tip cleaning process may be performed before step S750.

Still alternatively, when the repeated execution of the pre-nozzle tip cleaning process (S720) and the pre-bath cleaning process (S730) is completed (S740), only the bath cleaning process may be performed before step S750.

Yet still alternatively, when the repeated execution of the pre-nozzle tip cleaning process (S720) and the pre-bath cleaning process (S730) is completed (S740), the nozzle tip cleaning process and the bath cleaning process may be sequentially performed before step S750. FIG. 18 is a second exemplary flowchart of the cleaning method for the nozzle tip component (and its surroundings) of the substrate processing apparatus of FIG. 4.

The substrate treating apparatus 150b, which treats the substrate W using chemical solutions, and the method in which the substrate treating apparatus 150b cleans the nozzle tip member 410 and the standby port 420 have been described so far.

The present disclosure relates to an enhanced cleaning method for a photoresist nozzle tip. That is, the present disclosure relates to a selective enhanced cleaning method for removing sources of contamination in a photoresist nozzle. The present disclosure can perform pre-cleaning on the nozzle tip member 410 and its surroundings, as well as the internal surface of the standby port 420, before performing a thinner suck-back process. Accordingly, contaminants present in the nozzle tip member 410 and the standby port 420 can be removed, and only a clean thinner can be sucked back. Additionally, the number of pre-cleaning cycles can be selectively determined, thereby minimizing any associated time loss.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. A substrate treating apparatus comprising:
a substrate support unit supporting a substrate;
a spraying unit including a nozzle tip member, which has an outlet formed at an end thereof, and ejecting a treating solution onto the substrate using the nozzle tip member; and
a standby port accommodating the nozzle tip member that has completed the ejection of the treating solution,
wherein the substrate treating apparatus cleans the nozzle tip member and the inside of the standby port before the nozzle tip member sucks back a second chemical solution.

2. The substrate treating apparatus of claim 1, wherein the nozzle tip member and the standby port are sequentially cleaned.

3. The substrate treating apparatus of claim 2, wherein the standby port is cleaned before cleaning the nozzle tip member.

4. The substrate treating apparatus of claim 2, wherein the nozzle tip member is cleaned again after cleaning the standby port.

5. The substrate treating apparatus of claim 1, wherein the nozzle tip member and the inside of the standby port are cleaned repeatedly.

6. The substrate treating apparatus of claim 5, wherein a number of repetitions of the cleaning of the nozzle tip member and the standby port is determined in advance based on statistical data or is determined based on results of the inspection of surfaces of the nozzle tip member and the standby port.

7. The substrate treating apparatus of claim 1, wherein once the nozzle tip member is cleaned, the nozzle tip member is moved away from an internal space of the standby port.

8. The substrate treating apparatus of claim 7, wherein after the nozzle tip member is moved away, the inside of the standby port is cleaned.

9. The substrate treating apparatus of claim 1, wherein the second chemical solution is a thinner.

10. The substrate treating apparatus of claim 1, further comprising:
a first chemical solution supply unit supplying a first chemical solution into an internal space of the standby port;
a second chemical solution supply unit supplying a second chemical solution into the internal space of the standby port; and
a third chemical solution supply unit supplying a third chemical solution into the internal space of the standby port.

11. The substrate treating apparatus of claim 10, wherein the first chemical solution is for cleaning a surface of the nozzle tip member.

12. The substrate treating apparatus of claim 10, wherein the third chemical solution is for cleaning an inner surface of the standby port.

13. The substrate treating apparatus of claim 1, wherein the treating solution is for forming a photosensitive film on the substrate.

14. A cleaning method of a substrate treating apparatus comprising:
moving a nozzle tip member, which ejects a treating solution onto a substrate, into an internal space of a standby port;
cleaning the nozzle tip member;
cleaning the inside of the standby port; and
allowing the nozzle tip member to suck back a second chemical solution.

15. The cleaning method of claim 14, further comprising:
once the nozzle tip member is cleaned, moving the nozzle tip member away from an internal space of the standby port.

16. The cleaning method of claim 15, wherein the cleaning the inside of the standby port is performed after the moving the nozzle tip member.

17. The cleaning method of claim 14, wherein the cleaning the nozzle tip member and the cleaning the inside of the standby port are repeated.

18. The cleaning method of claim 14, further comprising:
cleaning the inside of the standby port before the cleaning the nozzle tip member.

19. The cleaning method of claim 14, further comprising:
cleaning the nozzle tip member again after the cleaning the inside of the standby port.

20. A substrate treating apparatus comprising:
a substrate support unit supporting a substrate;
a spraying unit including a nozzle tip member, which has an outlet formed at an end thereof, and ejecting a treating solution onto the substrate using the nozzle tip member; and
a standby port accommodating the nozzle tip member that has completed the ejection of the treating solution,
wherein
the nozzle tip member and the standby port are sequentially cleaned before the nozzle tip member sucks back a chemical solution,
the cleaning of the nozzle tip member and the cleaning of the standby port are repeated a plurality of times,
once the nozzle tip member is cleaned, the nozzle tip member moves away from the internal space of the standby port, and the inside of the standby port is cleaned after the nozzle tip member is moved away,
the standby port is cleaned once before cleaning the nozzle tip member,
the nozzle tip member is cleaned once again after cleaning the standby port, and
the chemical solution is a thinner.
